(19) United States
(12) Patent Application Publication
(10) Pub. No.: US 2004/0217202 A1
(43) Pub. Date: Nov. 4, 2004

(54) Airless conformal coating apparatus and method

(76) Inventor: Anthony J. Hynes, Ballston Spa, NY (US)

Correspondence Address: ARLEN L. OLSEN, SCHMEISER, OLSEN & WATTS, 3 LEAR JET LANE, SUITE 201, LATHAM, NY, 12110, US

(21) Appl. No.: 10/409,781

(22) Filed: Apr. 8, 2003

(51) Int. Cl. B05B 1/34

(52) U.S. Cl. 239/380

(57) ABSTRACT

The invention relates generally to an apparatus and method incorporating an airless conformal coating multiport spray nozzle on a multi-degree of freedom robotic apparatus. The airless conformal coating multiport spray nozzle includes multiple dispensing orifices through which a fluidic material is dispensed. Each of the dispensing orifices produces a bead-shaped spray pattern. Portions of adjacent bead-shaped spray pattern may overlap each other. The multiple dispensing orifices, in concert, produce a strip of fluidic material which allows an even distribution of the fluidic material across an article that is being coated, such as a printed circuit board.

### BACKGROUND OF THE INVENTION

1. Technical Field

The invention relates to an apparatus and method incorporating an airless conformal coating multiport spray nozzle on a multi-degree of freedom robotic apparatus.

2. Related Art

Conformal coatings are typically applied to a printed circuit board using devices such as spray guns or spray nozzles. Such devices generally include a liquid spray material that is atomized by compressed air, and is then directed toward the surface to be coated. The surface to be coated may be planar or curved, or a combination thereof. The spraying devices are commonly attached to an apparatus that provides accurate positional displacement relative to the article being coated.

There is now the increasingly common requirement of increasing throughput in the conformal coating process line. This desire for increased production has resulted in the development of resins and other conformal coating materials which are characterized by rapid drying times, as well as resins which may be applied without being mixed with air but which still produce a conformal coating, that is, airless conformal coating resin materials. Known spray nozzles utilized for applying such resins may produce a flat spray pattern resembling a leaf-shape or a triangular-shape. However, such leaf-shaped and triangular-shaped spray patterns have known deficiencies which arise from the patterns' susceptibility to several factors which affect the spray patterns consistency. These factors include variations in the supply pressure of the coating material being dispensed, the viscosity of the coating material, and the relative distance between the spray head and the article to which the spray is applied.

Thus, a need exists for a coating apparatus and method which utilizes a multiport nozzle and which overcomes the deficiencies of the related art.

### SUMMARY OF THE INVENTION

To overcome the above deficiencies, the present invention provides an apparatus and method which combine a multiport airless conformal coating nozzle and a precision robotic controller. The multiport airless conformal coating nozzle has a plurality of orifices through which a coating material is applied to a target workpiece, such as a printed circuit board or other article which is to be coated. In an embodiment, the spray pattern produced by the multiport spray head is characterized by a rectangular, cylindrical or columnar shape which results in a bead of coating material being deposited on the target workpiece. The bead thus deposited then spreads out on the target workpiece.

The precision robotic controller is used to accurately position the multiport airless conformal coating nozzle relative to the workpiece. The precision robotic controller is characterized by having a plurality of degrees of freedom, such as, for example, three or more degrees of freedom. The multiport airless conformal coating nozzle and the precision robotic controller, in novel combination, are operationally connected to a supply of conformal coating material. The conformal coating material may be delivered directly to the multiport airless conformal coating nozzle, or, alternatively, the conformal-coating material may be delivered to the multiport airless conformal coating nozzle via the precision robotic controller. In either case, the result is that a satisfactory conformal coating may be applied to a target workpiece using an airless delivery system, as well as with a faster throughput than is possible using known devices or methods.

In a first general aspect, the present invention provides a coating apparatus for dispensing a fluidic material, said coating apparatus comprising: a multiport spray nozzle for dispensing said fluidic material, wherein said multiport spray nozzle is shaped to produce a plurality of bead-shaped spray patterns via a corresponding plurality of dispensing orifices; a positioning mechanism operationally attached to said multiport spray nozzle, said positioning mechanism adapted to operate with a plurality of degrees of freedom; at least one fluid dispensing conduit, operationally coupled to said multiport spray nozzle and to a supply of fluidic material, said fluidic material dispensed via said multiport spray nozzle; and a control mechanism operationally coupled to said positioning mechanism, wherein said control mechanism is adapted to control said positioning mechanism to position said multiport spray nozzle, and wherein said control mechanism determines the flow of fluidic material to said multiport spray nozzle.

In a second general aspect, the present invention provides a method of applying a fluidic material, said method comprising the steps of: providing a multiport spray nozzle for dispensing said fluidic material, wherein said multiport spray nozzle produces a plurality of bead-shaped spray patterns; providing a positioning mechanism operationally attached to said multiport spray nozzle, said positioning mechanism further adapted to operate with a plurality of degrees of freedom; providing at least one fluidic material supply conduit, said supply conduit operationally coupled to said multiport spray nozzle, and to a supply of fluidic material, said fluidic material adapted for dispensing via said multiport spray nozzle; and providing a control mechanism operationally coupled to said positioning mechanism, wherein said control mechanism is adapted to direct said positioning mechanism to locate said multiport spray nozzle; and dispensing said plurality of bead-shaped spray patterns.

In a third general aspect, the present invention provides a coating application system comprising: a supply of fluidic coating material; a fluidic coating material control system for supplying said fluidic coating material to a material discharge system; a coating material supply system in communication with said material discharge system; an airless conformal coating multiport spray nozzle operationally coupled to said material discharge system, said multiport spray nozzle shaped to produce a plurality of bead-shaped spray patterns, said spray patterns in turn producing an overlapping series of coating strips; an in-line drive system, for supplying motive power to move said airless conformal coating multiport spray nozzle in at least one of a rotary direction and a lateral direction, said drive system operationally coupled to said airless conformal coating multiport spray nozzle; and a fluid passage extending through said airless conformal coating multiport spray nozzle, said fluid passage having a first end in communication with said material discharge system, and a second end in communication with a dispensing orifice.

In a fourth general aspect, the present invention provides a method for applying a coating material, said method comprising the steps of: providing an airless conformal coating multiport spray nozzle having a plurality of fluid dispensing orifices therein, wherein said dispensing orifices are operationally coupled to said coating material supply chamber, and wherein said dispensing orifices produce a plurality of adjacent coating material strips corresponding to a plurality of bead-shaped spray patterns emanating from said a plurality of fluid dispensing orifices; providing a positioning apparatus for positioning said airless conformal coating multiport spray nozzle, said positioning apparatus operating with at least three degrees of freedom; providing a supply of coating material to said airless conformal coating multiport spray nozzle; coupling said positioning apparatus to a drive means; positioning said airless conformal coating multiport spray nozzle; and projecting the coating material toward a surface to form a pattern.

In a fifth general aspect, the present invention provides an airless conformal coating apparatus comprising: a precision robotic controller; a drive motor; an end effector, having a first end and a second end, said first end operationally coupled to said drive motor; and an airless conformal coating multiport spray nozzle coupled to said end effector and shaped to dispense a fluidic material in a plurality of bead-shaped spray patterns.

In a sixth general aspect, the present invention provides a coated article of manufacture, said coated article comprising: a conformal coating on at least one of an exterior and an interior surface, wherein said conformal coating is applied via a multiport spray nozzle, wherein said multiport spray nozzle is shaped to produce a plurality of adjacent, bead-shaped spray patterns, said spray patterns in turn producing an adjacent series of coating strips, and wherein said multiport spray nozzle is operationally coupled to a robotic apparatus having multiple degrees of freedom, and further wherein said conformal coating is an airless resin.

The foregoing and other features and advantages of the invention will be apparent from the following more particular description of embodiments of the invention. It is to be understood that both the foregoing general description and the following detailed description are exemplary, but are not restrictive, of the invention.

### BRIEF DESCRIPTION OF THE DRAWINGS

The features of the present invention will best be understood from a detailed description of the invention and an embodiment thereof selected for the purposes of illustration and shown in the accompanying drawings in which:

FIG. 1 is a perspective view of a multiport spray nozzle in accordance with a first embodiment of the present invention;

FIG. 2 is a perspective view of a multiport spray nozzle in accordance with a second embodiment of the present invention;

FIG. 3A is a perspective view of a multiport spray nozzle shown in an application mode in accordance with an embodiment of the present invention;

FIG. 3B is a sectional view of a portion of FIG. 3A depicting a coating material as initially applied;

FIG. 3C is a sectional view of a portion of FIG. 3A depicting a coating material after a time period has elapsed following application;

FIG. 4 is a perspective view of a coating application end effector, including a multiport spray nozzle, of the present invention;

FIG. 5 is a front view of a robotic precision controller having a multiport airless conformal coating nozzle of the present invention; and

FIG. 6 is a top view of a robotic precision controller having a multiport airless conformal coating nozzle of the present invention.

### DETAILED DESCRIPTION OF THE INVENTION

Although certain embodiments of the present invention will be shown and described in detail, it should be understood that various changes and modifications may be made without departing from the scope of the appended claims. The scope of the present invention will in no way be limited to the number of constituting components, the materials thereof, the shapes thereof, the relative arrangement thereof, etc., and are disclosed simply as an example of an embodiment. The features and advantages of the present invention are illustrated in detail in the accompanying drawings, wherein like reference numerals refer to like elements throughout the drawings.

As a preface to the detailed description, it should be noted that, as used in this specification and the appended claims, the singular forms “a”, “an” and “the” include plural referents, unless the context clearly dictates otherwise.

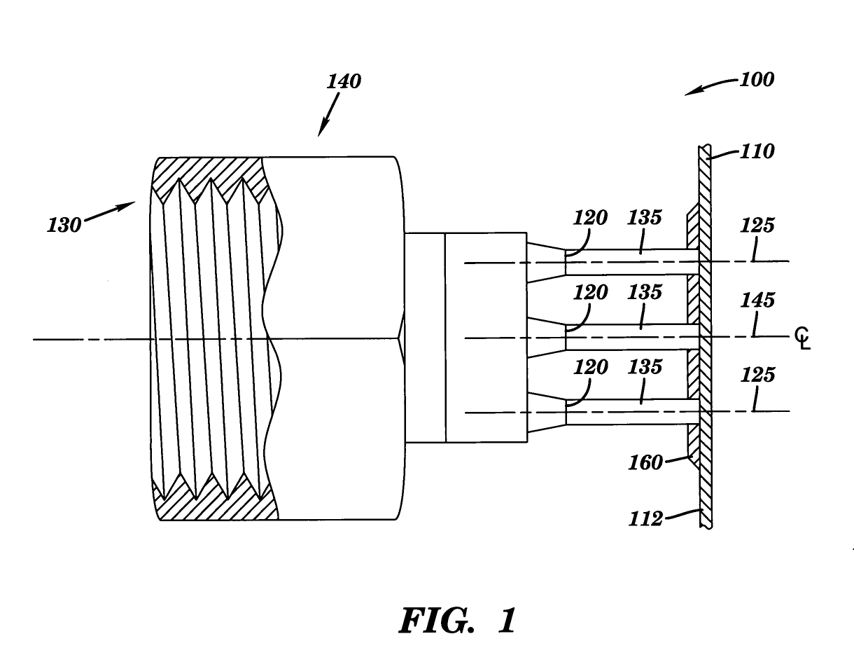

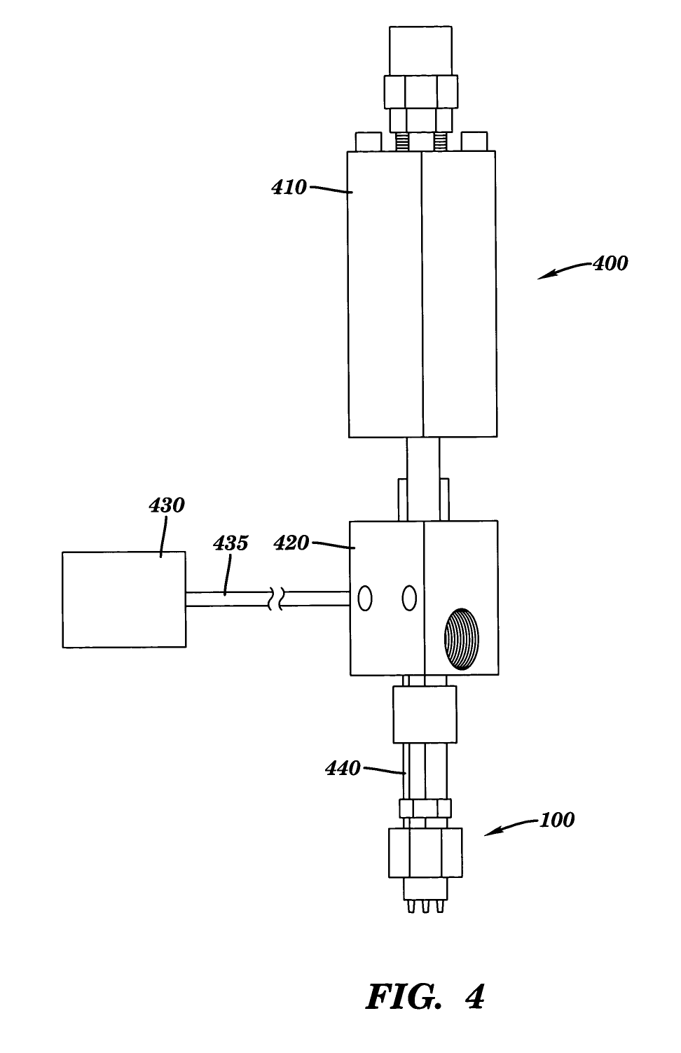

Referring to FIG. 1, there is illustrated a perspective view of a multiport spray nozzle 100 in accordance with an embodiment of the present invention. The multiport spray nozzle 100 includes a plurality of dispensing orifices 120 through which a fluidic material is applied to the surface 112 of a target workpiece 110 such as, inter alia, a planar substrate or the curved interior of a vessel. The multiport spray nozzle 100 may include dispensing orifices whose centerlines 125 are parallel or coaxial with the centerline 145 of the multiport spray nozzle 100. The coupling member 140 of the multiport spray nozzle 100 may include screw threads 130, or other releasable attachment means, which facilitate coupling the multiport spray nozzle 100 to related mounting portions of an end effector, such as end effector 400 (FIG. 4), of an airless conformal coating apparatus. The fluidic material 135 may be, inter alia, an airless conformal coating resin.

The multiport spray nozzle 100 embodied in FIG. 1 produces three bead-shaped spray patterns 135. The bead-shaped spray patterns 135 produced by the multiport spray nozzle 100 may be characterized by having a rectangular, cylindrical or columnar shape or a circular or elliptical cross-sectional shape which results in a similar bead of coating material being deposited on the target workpiece. In alternative embodiments, the bead-shaped spray patterns 135 may have a cross-sectional shape ranging from substantially flat to any other suitable geometric cross-sectional shape, depending upon the intended application.

A multiport spray nozzle 100 of the type shown in FIG. 1 may be derived by combining a plurality (i.e., two or more) individual spray nozzles on a single spray head (not shown). The individual spray nozzles on such a combination spray head may be placed so that the combined bead-shaped spray patterns 135 eventually produce a single continuous layer or strip of fluidic material on the target workpiece 110.

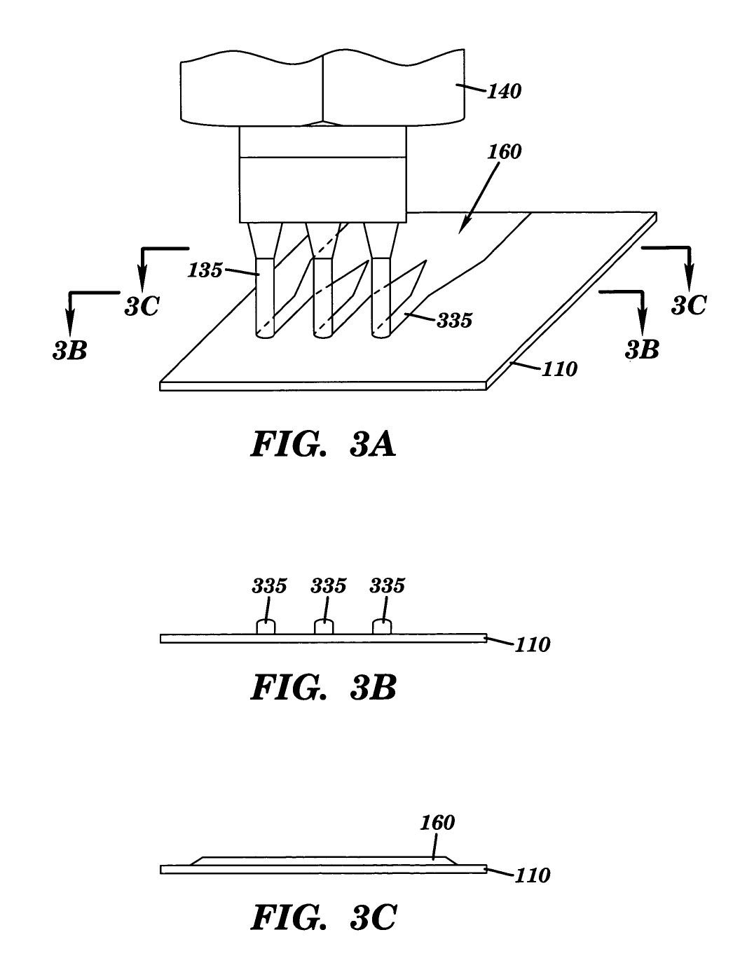

Referring to FIG. 3, upon application to the target workpiece 110, each of the bead-shaped spray patterns 135 forms an elongated, continuous bead 335 on the surface of the target workpiece 110. As shown in FIG. 3B, the each bead 335 has a-uniform and fairly compact cross section. However, as time passes following deposition of the beads 335, each bead 335 will begin to collapse so that the bead spreads across the surface of the target workpiece 110. FIG. 3C shows the a cross-sectional view of the series of beads 335 after a period of time has elapsed sufficient to allow individual beads 335 to spread sideways and to blend together, thus forming a continuous conformal coating layer 160. In this manner a continuous and conformal coating may be formed on the target workpiece 110.

The degree of this spreading or flow of the beads 335, and the thickness of the resultant coating material layer, is dependent on several factors, including, inter alia, the size of the initially deposited bead, the viscosity of the coating material, the composition of the coating material, the topography of the surface upon which the bead is deposited, and ambient environmental conditions.

Alternatively, the multiport spray nozzle 100 may be characterized in that it produces bead-shaped spray patterns 135 which are not only adjacent, but which are substantially touching or overlapping when they are deposited.

In an embodiment, the fluidic material is a resin having a viscosity in the range 5-700 cps which is applied without the aid of forced air to propel the resin. In an alternative embodiment, the fluidic material is a resin applied with an extrusive pressure in the range of 5-500 kg/cm².

Further, the dispensing orifices of the individual spray nozzles may be essentially identical to one another, such that each individual spray nozzle produces a closely similar bead-shaped spray pattern. However, in an alternative embodiment, the individual bead-shaped spray patterns may also be not identical, so that each individual nozzle produces a different spray pattern. In such embodiment, several different spray nozzles may be combined to produce a dissimilar or non-symmetrical overlapping spray pattern on the target workpiece or other article of manufacture.

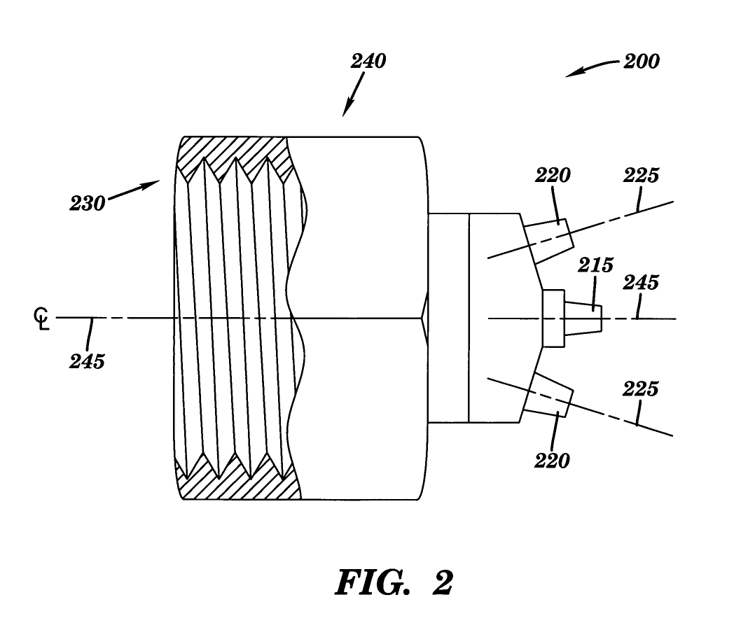

Alternatively, as shown in FIG. 2, the centerlines 225 of some dispensing orifices 220 may be offset from the centerline 245 of the multiport spray nozzle 200, as shown in FIG. 2. The coupling member 240 of the multiport spray nozzle 200 may include screw threads 230 which facilitate coupling the multiport spray nozzle 200 to the related mounting portions of an end effector 300 (FIG. 3) of an airless conformal coating apparatus.

Moreover, multiport spray nozzles of the type depicted in FIGS. 1 and 2, however, have not heretofore been combined with a precision robotic controller to form an airless conformal coating apparatus. Referring to FIG. 4, such novel combination could include a known fluidic material reservoir 430 which is operationally coupled to end effector 400, to which an multiport spray nozzle 100 is also operationally and releasably attached.

The multiport spray nozzle 100 is attached to an apparatus, such as a multi-degree of freedom robotic positioning apparatus, that provides accurate positional displacement relative to the article being coated. Therefore, when the multiport spray nozzle 100 is moved in a horizontal direction relative to a surface of a targeted workpiece, the multiport spray nozzle 100 can coat a wide area, and in this matter an entire surface maybe expeditiously and efficiently coated.

In operation, a fluidic material (not shown) to be applied as a coating, is supplied under pressure to the multiport spray nozzle 100. The fluidic material is then forced through the plurality of dispensing orifices 120. At the same time, the multiport spray nozzle 100 is caused to travel longitudinally at a desired height above the surface of the target workpiece upon which the coating is to be deposited. The fluidic material which issues from the plurality of dispensing orifices 120 will produce an elongate spray pattern on the surface of the target workpiece. The spray pattern formed by the resultant deposited coating material may have a clearly defined edge. Also, the amount of spattering, or extraneous coating material deposited outside the spray pattern, can be minimized or eliminated.

In an alternative embodiment, multiport spray nozzle 100 may be rotated about an axis relatively orthogonal to the surface of the target workpiece, resulting in circular coating patterns. In a further alternative embodiment, multiport spray nozzle may 100 be rotated about an axis relatively parallel to the surface of the target workpiece, for applications such as, inter alia, coating the interior or exterior surfaces of a hollow vessel.

FIG. 4 is a perspective view of a coating application end effector 400 including a multiport spray nozzle 100 of the present invention. Coating application end effector 400 includes a supply of fluidic material 430 to be applied as a coating, and a fluidic material system 410 which controls the flow of the fluidic material 430, via fluid dispensing conduit 435, in or to the coating application end effector 400. A fluidic material supply system 420 is operationally coupled to the fluidic material control system 410 and to a material discharge system 440. The material discharge system 440 includes multiport spray nozzle 100.

As used herein, the term “coating applicator” refers to a portion of a conformal coating system from which the conformal coating is dispensed, such as, for example, a multiport spray nozzle. As used herein, the term “end effector” refers to any device(s) attached to an x, y, z, or other axis of movement to perform various applications, such as, for example, dispensing, pick and place, routing, etc.

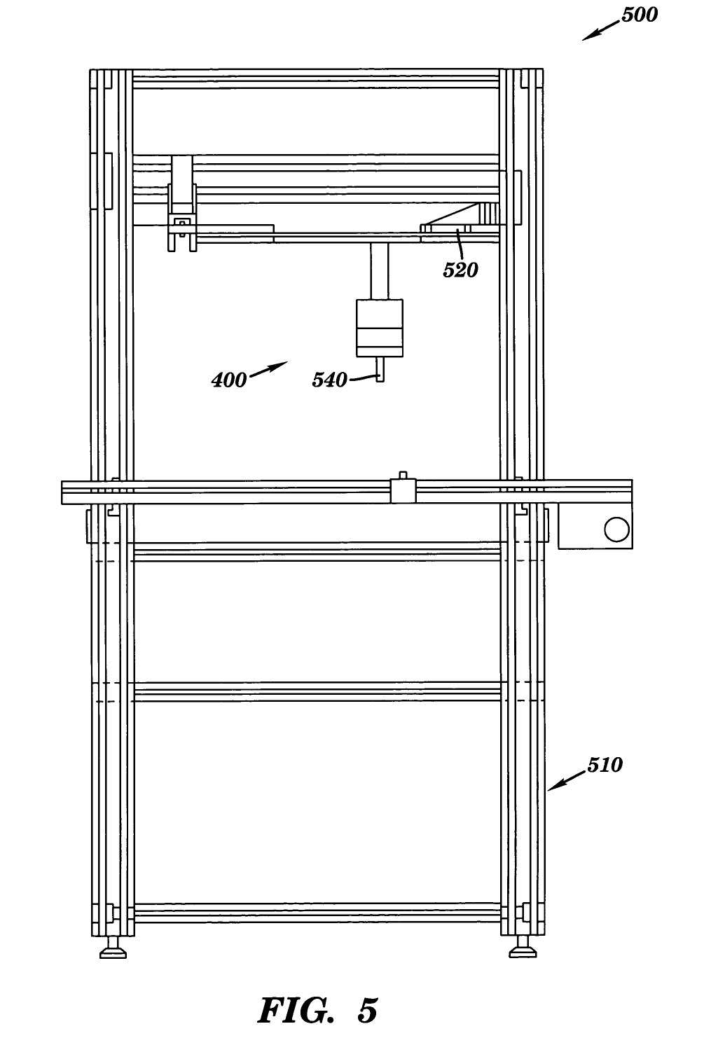

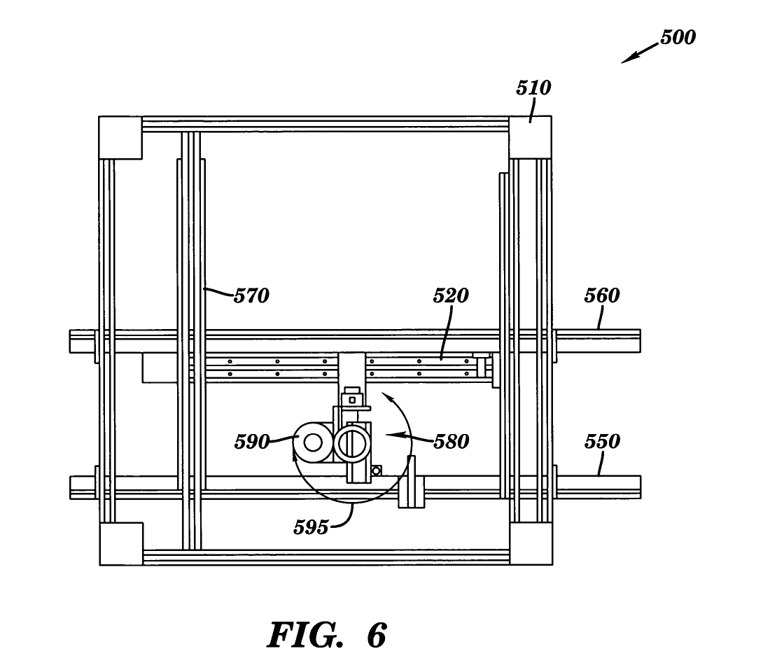

FIG. 5 is a front view of an improved airless conformal coating apparatus 500, which is also shown in FIG. 6. Airless conformal coating apparatus 500 includes, inter alia, end effector 400 to which is operationally attached multiport spray nozzle 100. End effector 400 dispenses fluidic material through multiport spray nozzle 100 to dispense a conformal coating pattern.

FIG. 6 is a top view of an exemplary precision robotic controller or conformal coating apparatus 500 according to the present invention. System 500, according to the present invention, comprises frame 510, Y axis ball screw slide 520, X axis ball screw slide 570 and end effector 580. End effector 580 is capable of rotation about the φ axis 595. End effector 580 moves left and right along the Y axis by sliding along Y axis ball screw slide 520. Similarly, end effector 580 moves back and forth along with frame members 560 and 550 and Y axis ball screw slide 520, along X axis ball screw slide 570.

The embodiments described above are directed toward the coating of substantially planar articles, such as, inter alia, printed circuit boards. However, in an alternative application, the multiport spray nozzle 100 of the present invention could be utilized to coat the interior of hollow articles, such as, inter alia, syringes. In this embodiment, the multiport spray nozzle 100, or a plurality thereof, could be operationally mounted to an automated machine. The automated machine would provide positioning of the multiport spray nozzle 100 in the syringe, so that the entire interior surface of the syringe could be coated.

The foregoing description of the present invention has been presented for purposes of illustration and description. It is not intended to be exhaustive or to limit the invention to the precise form disclosed or to the materials in which the form may be embodied, and many modifications and variations are possible in light of the above teaching. For instance, the multiport spray nozzle of the present invention may be embodied of inter alia, 300 series stainless steel, for use in a printed circuit board coating applications. Further, the multiport spray nozzle of the present invention is not limited to applying ultraviolet (UV) acrylic gels, and moisture and thermal cure silicones to circuit boards, but also can used to spray other materials such as paints, oils, inks, etc. The multiport spray nozzle can also be used to spray materials onto other surfaces besides circuit boards. The multiport spray nozzle of the present invention can spray materials with viscosities in the range from about 0 centipoise to about 50,000 centipoise. Such modifications and variations that may be apparent to a person skilled in the art are intended to be included within the scope of this invention as defined by the accompanying claims.

What is claimed is:

1. A coating apparatus for dispensing a fluidic material, said coating apparatus comprising:
a multiport spray nozzle for dispensing said fluidic material, wherein said multiport spray nozzle is shaped to produce a plurality of bead-shaped spray patterns via a corresponding plurality of dispensing orifices;
a positioning mechanism operationally attached to said multiport spray nozzle, said positioning mechanism adapted to operate with a plurality of degrees of freedom;
at least one fluid dispensing conduit, operationally coupled to said multiport spray nozzle and to a supply of fluidic material, said fluidic material dispensed via said multiport spray nozzle; and
a control mechanism operationally coupled to said positioning mechanism, wherein said control mechanism is adapted to control said positioning mechanism to position said multiport spray nozzle, and wherein said control mechanism determines the flow of fluidic material to said multiport spray nozzle.

2. The coating apparatus according to claim 1, wherein the multiport spray nozzle is an airless conformal coating multiport spray nozzle.

3. The coating apparatus according to claim 2, wherein the airless conformal coating multiport spray nozzle comprises a plurality of openings through which the fluidic material is dispensed.

4. The coating apparatus according to claim 3, wherein the plurality of bead-shaped spray patterns include adjacent spray patterns.

5. The coating apparatus according to claim 4, wherein each bead-shaped spray pattern provides a deposited fluidic material strip, and further wherein adjacent deposited fluidic material strips overlap each other.

6. The coating apparatus according to claim 2, wherein the airless conformal coating multiport spray nozzle is releasably attached to said positioning mechanism.

7. The coating apparatus according to claim 6, wherein the airless conformal coating multiport spray nozzle is releasably attached to said positioning mechanism via a threaded connection.

8. The coating apparatus according to claim 2, wherein the positioning mechanism is adapted to operate with three degrees of freedom.

9. The coating apparatus according to claim 1, wherein the fluidic material is an airless conformal coating resin.

10. The coating apparatus according to claim 4, wherein the plurality of openings through which the fluidic material is dispensed each produce an essentially identical bead-shaped spray pattern.

11. The coating apparatus according to claim 4, wherein at least one of the plurality of openings through which the fluidic material is dispensed produces a dissimilar bead-shaped spray pattern.

12. A method of applying a fluidic material, said method comprising the steps of:
providing a multiport spray nozzle for dispensing said fluidic material, wherein said multiport spray nozzle produces a plurality of bead-shaped spray patterns;
providing a positioning mechanism operationally attached to said multiport spray nozzle, said positioning mechanism further adapted to operate with a plurality of degrees of freedom;
providing at least one fluidic material supply conduit, said supply conduit operationally coupled to said multiport spray nozzle, and to a supply of fluidic material, said fluidic material adapted for dispensing via said multiport spray nozzle; and
providing a control mechanism operationally coupled to said positioning mechanism, wherein said control mechanism is adapted to direct said positioning mechanism to locate said multiport spray nozzle; and
dispensing said plurality of bead-shaped spray patterns.

13. The method according to claim 12, the multiport spray nozzle being an airless conformal coating multiport spray nozzle.

14. The method according to claim 13, the airless conformal coating multiport spray nozzle including a plurality of dispensing orifices through which the fluidic material is dispensed.

15. The method according to claim 14, the plurality of bead-shaped spray patterns including adjacent spray patterns.

16. The method according to claim 14, the airless conformal coating multiport spray nozzle releasably attached to said positioning mechanism.

17. The method according to claim 16, the airless conformal coating multiport spray nozzle releasably attached to said positioning mechanism via a threaded connection.

18. The method according to claim 15, the positioning mechanism adapted to operate with three degrees of freedom.

19. A coating application system comprising:
a supply of fluidic coating material;
a fluidic coating material control system for supplying said fluidic coating material to a material discharge system;
a coating material supply system in communication with said material discharge system;
an airless conformal coating multiport spray nozzle operationally coupled to said material discharge system, said multiport spray nozzle shaped to produce a plurality of bead-shaped spray patterns, said spray patterns in turn producing an overlapping series of coating strips;
an in-line drive system, for supplying motive power to move said airless conformal coating multiport spray nozzle in at least one of a rotary direction and a lateral direction, said drive system operationally coupled to said airless conformal coating multiport spray nozzle; and
a fluid passage extending through said airless conformal coating multiport spray nozzle, said fluid passage having a first end in communication with said material discharge system, and a second end in communication with a dispensing orifice.

20. The coating application system of claim 19, wherein said material control system includes a material inlet and a valve system for selectively supplying material from the material inlet to the material discharge system.

21. A method for applying a coating material, said method comprising the steps of:
providing an airless conformal coating multiport spray nozzle having a plurality of fluid dispensing orifices therein, wherein said dispensing orifices are operationally coupled to said coating material supply chamber, and wherein said dispensing orifices produce a plurality of adjacent coating material strips corresponding to a plurality of bead-shaped spray patterns emanating from said a plurality of fluid dispensing orifices;
providing a positioning apparatus for positioning said airless conformal coating multiport spray nozzle, said positioning apparatus operating with at least three degrees of freedom;
providing a supply of coating material to said airless conformal coating multiport spray nozzle;
coupling said positioning apparatus to a drive means;
positioning said airless conformal coating multiport spray nozzle; and
projecting the coating material toward a surface to form a pattern.

22. The method of claim 21, further comprising the step of moving the rotating airless conformal coating multiport spray nozzle in a lateral direction.

23. The method of claim 21, further comprising the steps of:
providing one or more hollow articles having an interior surface to be coated; and
providing a positioning system to guide said airless conformal coating multiport spray nozzle into said hollow object.

24. An airless conformal coating apparatus comprising:
a precision robotic controller;
a drive motor;
an end effector, having a first end and a second end, said first end operationally coupled to said drive motor; and
an airless conformal coating multiport spray nozzle coupled to said end effector and shaped to dispense a fluidic material in a plurality of bead-shaped spray patterns.

25. The airless conformal coating apparatus of claim 24, wherein said airless conformal coating multiport spray nozzle has a first centerline, a first dispensing orifice positioned at said second end of said end effector, said first dispensing orifice has a centerline coaxial with said first centerline, and at least one second dispensing orifice displaced from said first dispensing orifice, said second dispensing orifice has a second centerline, and wherein said second centerline is substantially parallel to said first centerline.

26. The airless conformal coating apparatus of claim 25, wherein the first centerline and the second centerline form an oblique angle.

27. The airless conformal coating apparatus of claim 25, wherein said end effector is rotatable about its longitudinal axis.

28. The airless conformal coating apparatus of claim 25, wherein said end effector is rotatable about its transverse axis.

29. The airless conformal coating apparatus of claim 25, wherein said airless conformal coating multiport spray nozzle is coupled to said end effector via a releasable coupling.

30. The airless conformal coating apparatus of claim 29, wherein said releasable coupling is a threaded connection.

31. The airless conformal coating apparatus of claim 24, wherein said airless conformal coating multiport spray nozzle

32. A coated article of manufacture, said coated article comprising:
a conformal coating on at least one of an exterior and an interior surface, wherein said conformal coating is applied via a multiport spray nozzle, wherein said multiport spray nozzle is shaped to produce a plurality of adjacent, bead-shaped spray patterns, said spray patterns in turn producing an adjacent series of coating strips, and wherein said multiport spray nozzle is operationally coupled to a robotic apparatus having multiple degrees of freedom, and further wherein said conformal coating is an airless resin.
